(19) United States
(12) Patent Application Publication
(10) Pub. No.: US 2014/0355351 A1
(43) Pub. Date: Dec. 4, 2014

(54) CONTROLLER

(71) Applicant: KABUSHIKI KAISHA TOSHIBA, Tokyo (JP)

(72) Inventors: Masaki UNNO, Kanagawa (JP); Masanobu SHIRAKAWA, Kanagawa (JP)

(73) Assignee: KABUSHIKI KAISHA TOSHIBA, Tokyo (JP)

(21) Appl. No.: 14/189,913

(22) Filed: Feb. 25, 2014

(30) Foreign Application Priority Data
May 30, 2013 (JP) 2013-114517

(51) Int. Cl. G11C 16/24; G06F 12/02; G11C 16/04

(52) U.S. Cl. CPC G11C 16/24; G11C 16/0483; G06F 12/0246; G06F 2212/7207
USPC 365/185.17; 711/103

(57) ABSTRACT

A controller for a memory device having a bit line, a source line, and a plurality of strings of memory cell transistors connected between the bit line and the source line, is configured to update first and second values for each string when read and write operations are carried out on the strings, the first value for a first string being updated when a read or write operation is carried out on a memory cell transistor of the first string and the second value being updated when a read or write operation is carried out on a memory cell transistor of a second string that is different from the first string.

### CROSS-REFERENCE TO RELATED APPLICATION

This application is based upon and claims the benefit of priority from Japanese Patent Application No. 2013-114517, filed May 30, 2013, the entire contents of which are incorporated herein by reference.

### FIELD

Embodiments described herein relate generally to a controller.

### BACKGROUND

A NAND type flash memory with a three-dimensional structure manufactured using a BiCS manufacturing technique is referred to in the art as BiCS memory and has a controller which controls read/write operations performed on the BiCS memory.

### DESCRIPTION OF THE DRAWINGS

FIG. 1 is a block diagram of a memory controller and a memory according to an exemplary embodiment.

FIG. 2 is a block diagram of the memory according to the exemplary embodiment.

FIG. 3 is a perspective view of a part of a memory cell array according to the exemplary embodiment.

FIG. 4 is a circuit diagram of a part of the memory cell array according to the exemplary embodiment.

FIG. 5 is a diagram illustrating various examples of a logical block according to the exemplary embodiment.

FIG. 6 is a cross-sectional view of a cell transistor according to the exemplary embodiment.

FIG. 7 is a diagram illustrating an example of a voltage bias that is applied when data is read from or written to the memory according to the exemplary embodiment.

FIG. 8 is a diagram illustrating an example of a management table maintained by the memory controller according to the exemplary embodiment.

FIG. 9 is a flowchart illustrating updating of the management table when erasing is performed, according to the exemplary embodiment.

FIG. 10 is a flowchart illustrating updating of the management table when reading is performed, according to the exemplary embodiment.

FIG. 11 is a flowchart illustrating updating of the management table when writing is performed, according to the exemplary embodiment.

FIG. 12 is a flowchart illustrating data movement using the management table, according to the exemplary embodiment.

FIG. 13 is a diagram illustrating an example of multi-plane access according to the exemplary embodiment.

FIG. 14 is a time chart showing voltage level changes when reading is performed according to the exemplary embodiment.

FIG. 15 is a time chart showing voltage level changes when reading followed by data movement is performed according to the exemplary embodiment.

### DETAILED DESCRIPTION

In general, according to one embodiment, a controller for a memory device having a bit line, a source line, and a plurality of strings of memory cell transistors connected between the bit line and the source line, is configured to update first and second values for each string when read and write operations are carried out on the strings, the first value for a first string being updated when a read or write operation is carried out on a memory cell transistor of the first string and the second value being updated when a read or write operation is carried out on a memory cell transistor of a second string that is different from the first string.

When the memory device is a NAND type flash memory, a single string includes a plurality of cell transistors connected in series to each other. When data is written, a writing voltage Vpgm is applied to a word line of a selected memory cell transistor of a certain string. On the other hand, a non-selection voltage Vpass is applied to word lines of the other unselected memory cell transistors of the string. Due to the application of the voltage Vpass to the unselected memory cell transistors, the memory cell transistors may undergo a threshold voltage fluctuation. In other words, a writing disturbance occurs. In a NAND type flash memory (referred to as a planar memory) with a non-three-dimensional structure, only a single string is connected to a single bit line in a single block. Therefore, due to writing of data to a single block, the voltage Vpgm is applied once to each memory cell, and the voltage Vpass is applied thereto the number of times which is the same as (the number of cell transistors of a single string−1). In the planar memory, this number of times is the worst case of the writing disturbance. This is because, in the NAND type flash memory having a planar memory structure, data can be written only to a block for which data erasing has been completed, and the influence of disturbance on the memory cell is reset by the erasure. For this reason, even in the worst case, various voltages are determined such that writing errors do not occur in an unselected cell, thereby properly handling the writing errors.

On the other hand, in the BiCS memory, a plurality of strings are connected to a single bit line in a single block. For this reason, writing disturbance different from that experienced in the planar memory occurs in the BiCS memory. Therefore, the controller for the planar memory cannot be used for the BiCS memory.

Hereinafter, an exemplary embodiment will be described with reference to the drawings. In addition, in the following description, constituent elements which have substantially same function and configuration are given the same reference numeral, and a repeated description will be made only as needed. It is noted that the drawings are schematic. Each exemplary embodiment described below illustrates a device or a method for embodying the technical spirit of this exemplary embodiment, and the technical spirit of the exemplary embodiment does not specify a material, a shape, a structure, a disposition, and the like of a constituent element to the following.

Each functional block may be realized in either of hardware and software of a computer, or through a combination thereof. For this reason, each functional block will be substantially described below from the viewpoint of the function thereof in order to clarify that each functional block can be either hardware or software. How to realize the described functions depends on various factors. A person skilled in the art may realize the described functions in various ways for each specific exemplary embodiment, and any such realization method is included in the scope of the exemplary embodiment. In addition, it is not essential that each functional block be differentiated as in the following. For example, some functions may be performed by a functional block different from the depicted functional block. Further, a depicted functional block may be divided into finer sub-functional blocks. Exemplary embodiments are not limited by any specific functional block.

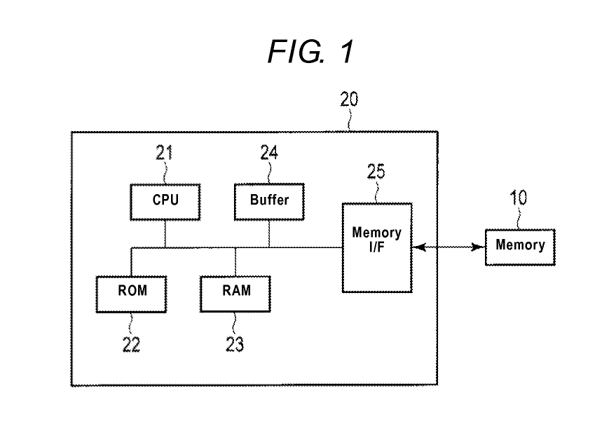

FIG. 1 is a block diagram of a memory controller and a memory according to an exemplary embodiment. A memory controller 20 communicates with an external device (not shown) (for example, a host device) so as to control a memory 10. In other words, the memory controller 20 receives commands such as a writing command, a reading command, and an erasure command from the external device. In addition, the memory controller 20 accesses the memory 10 on the basis of the commands. The memory controller 20 includes constituent elements such as a central processing unit (CPU) 21, a read only memory (ROM) 22, a random access memory (RAM) 23, a buffer 24, and a memory interface 25. The constituent elements are connected to each other via a bus. The memory controller 20 may further include an interface (for example, a host interface) for communication with the external host device.

The CPU 21 controls the overall operation of the memory 10 on the basis of a control program. The ROM 22 stores firmware such as a control program used by the CPU 21. The RAM 23 is used as a work area of the CPU 21 and stores a control program, various tables, or the like. The buffer 24 temporarily stores data. The memory interface 25 interfaces the memory controller 20 with the memory 10.

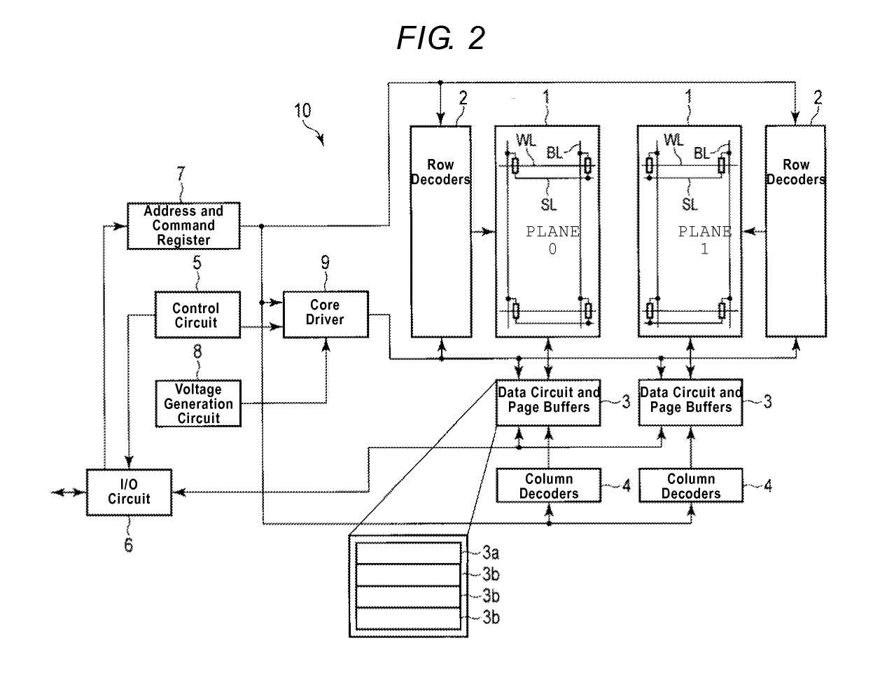

FIG. 2 is a block diagram of the memory 10 according to the exemplary embodiment. As shown in FIG. 2, the memory 10 includes constituent elements such as memory cell arrays 1, row decoders 2, data circuit and page buffers 3, column decoders 4, a control circuit 5, an input and output circuit 6, an address and command register 7, a voltage generation circuit 8, and a core driver 9.

The memory 10 includes a plurality of (two memory cell arrays are exemplified) memory cell arrays 1. The memory cell array 1 is referred to as a plane in some cases. The memory cell array 1 includes a plurality of physical blocks. Each physical block includes a plurality of memory cells, word lines WL, bit lines BL, source lines SL, and the like.

A set of the row decoder 2, the data circuit and page buffer 3 and the column decoder 4 is provided for each memory cell array 1. The row decoder 2 receives a block address signal or the like from the address and command register 7, and receives a word line control signal or a gate line control signal from the core driver 9. The row decoder 2 selects a physical block, a word line, and the like on the basis of received block address signal, word line control signal and selection gate line control signal.

The data circuit and page buffer 3 temporarily holds data read from the memory cell array 1, and receives data to be written from an external device of the memory 10 so as to write the received data to a selected memory cell. The data circuit and page buffer 3 includes a sense amplifier 3a. The sense amplifier 3a includes a plurality of sense amplifiers which are respectively connected to a plurality of bit lines BL so as to amplify voltages on the bit lines BL. The memory 10 may hold data of two or more bits in a single memory cell. For this reason, the data circuit and page buffer 3 includes, for example, three data caches 3b. The first data cache 3b holds one of lower page data and upper page data, the second data cache 3b holds the other of the lower page data and the upper page data. The lower page data is formed by a set of lower bits in respective 2-bit data items of a plurality of related memory cells. The upper page data is formed by a set of upper bits in respective 2-bit data items of a plurality of related memory cells. The third data cache 3b holds temporary data which is rewritten to a memory cell, for example, based on a result of verification reading.

The column decoder 4 receives a column address signal from the address and command register 7, and decodes the received column address signal. The column decoder 4 controls inputting and outputting of data to and from the data circuit and page buffer 3 on the basis of the decoded address signal.

The control circuit 5 receives commands for instructing reading, writing, erasing, and the like from the address and command register 7. The control circuit 5 controls the voltage generation circuit 8 and the core driver 9 according to a predetermined sequence on the basis of the instructions of the commands. The voltage generation circuit 8 generates various voltages in response to an instruction from the control circuit 5. The core driver 9 controls the row decoder 2 and the data circuit and page buffer 3 so as to control the word line WL and the bit line BL, in response to an instruction from the control circuit 5. The input and output circuit 6 controls inputting of a command, an address, and data from an external device of the memory 10 or outputting thereof to the external device of the memory 10.

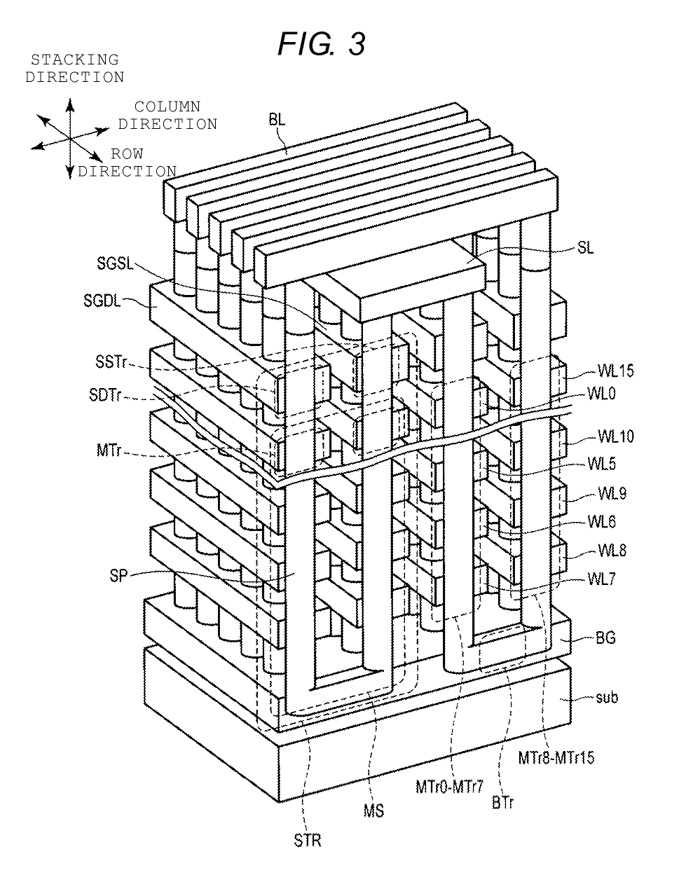

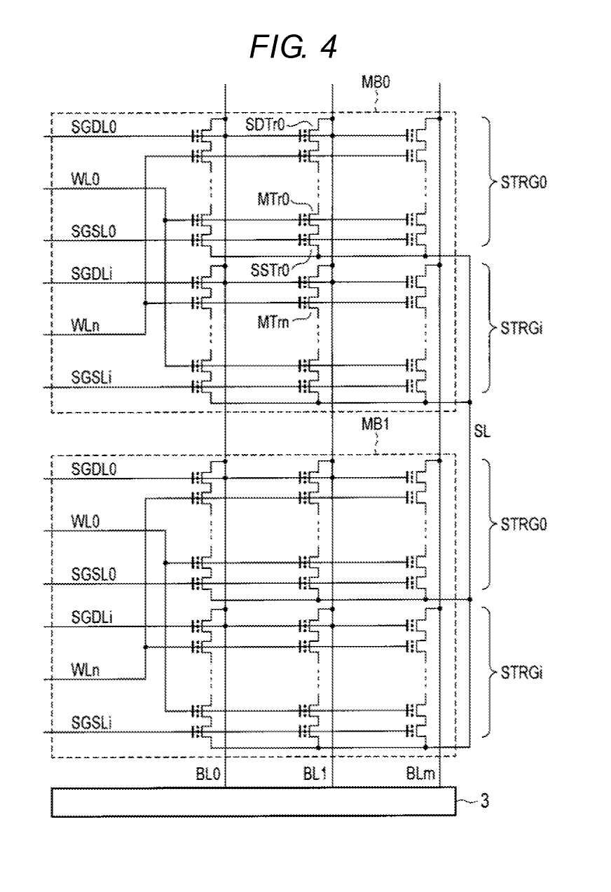

The memory cell array 1 has elements and connections shown in FIGS. 3 and 4. FIG. 3 is a perspective view of a part of the memory cell array according to the exemplary embodiment. FIG. 4 is a circuit diagram of a part (two physical blocks MB) of the memory cell array according to the exemplary embodiment. As shown in FIGS. 3 and 4, the memory cell array 1 includes a plurality of bit lines BL, a plurality of source (cell source) lines SL, and a plurality of physical blocks MB. The source lines SL extend in the row direction. The bit lines BL extend in the column direction. The column direction is perpendicular to the row direction. A plurality of physical blocks MB are arranged with a predetermined pitch in the column direction. In each physical block MB, a single bit line BL is connected to (i+1) strings STR. In FIG. 3, two strings STR are shown for each bit line.

A single string STR has a memory string MS, a source side selection gate transistor SSTr, and a drain side selection gate transistor SDTr. The memory string MS is located on an upper side in a direction in which a substrate sub is stacked. The memory string MS includes (n+1) (where n is, for example, 15) memory cell transistors MTr0 to MTr15 connected in series to each other, and a back gate transistor BTr. If it is not necessary to differentiate reference signs (for example, a cell transistor MTr) with numbers added to the ends from each other, a reference sign with no number added to the end is used, and this reference sign is assumed to indicate reference signs with all numbers added to the ends. The cell transistors MTr0 to MTr7 are arranged in this order in a direction of becoming close to the substrate sub in the stacking direction. The cell transistors MTr8 to MTr15 are arranged in this order in a direction of becoming distant from the substrate sub in the stacking direction. The cell transistor MTr includes a semiconductor pillar SP, an insulating film on a surface of the semiconductor pillar SP, and a word line (control gate) WL which will be described later. The back gate transistor BTr is connected between the cell transistors MTr7 and MTr8 located at the lowermost part.

The selection gate transistors SSTr and SDTr are located on an upper side in the stacking direction of the cell transistors MTr0 and MTr15 located at the uppermost part. A drain of the transistor SSTr is connected to a source of the cell transistor MTr0. A source of the transistor SDTr is connected to a drain of the cell transistor MTr15. A source of the transistor SSTr is connected to the source line SL. A drain of the transistor SDTr is connected to the bit line BL.

A plurality of strings arranged in the row direction form a string group. For example, all of a plurality of strings which are arranged in the row direction and are respectively connected to all of the bit lines BL form string groups. In each string group, gates of the cell transistors MTr0 of each of a plurality of strings are connected in common to the word line WL0. Similarly, in each string group, gates of the cell transistors MTrX of each of a plurality of strings are connected in common to the word line WLX. The word line WL extends in the row direction. Gates of the back gate transistors BTr are connected in common to a back gate line BG.

In each string group STRG, the gates of the transistors SDTr of each of a plurality of strings STR are connected in common to a drain side selection gate line SGDL. In the respective strings, the drains of the transistors SDTr of a plurality of strings STR are connected in common to the same bit line BL. The selection gate line SGDL extends in the row direction. The selection gate lines SGDL0 to SGDLi are respectively provided for use in the string groups STRG0 to STRGi.

In each string group STRG, the gates of the transistors SSTr of each of a plurality of strings STR are connected in common to a source side selection gate line SGSL. The sources of the transistors SSTr of two strings STR arranged in the column direction are connected to the same source line SL. In each string group STRG, the sources of the transistors SSTr of each of a plurality of strings STR are connected to the same source line SL. The selection gate line SGSL and the source line SL extend in the row direction. The source side selection gate lines SGSL0 to SGSLi are provided for use in the string groups STRG0 to STRGi.

A configuration of the memory cell array 1 is disclosed in U.S. patent application Ser. No. 12/407,403, filed on Mar. 19, 2009, entitled “three-dimensional stacked nonvolatile semiconductor memory”. In addition, a configuration thereof is disclosed in U.S. patent application Ser. No. 12/406,524, filed on Mar. 18, 2009, entitled “three-dimensional stacked nonvolatile semiconductor memory”, U.S. patent application Ser. No. 12/679,991, filed on Mar. 25, 2010, entitled “nonvolatile semiconductor memory device and manufacturing method thereof”, and U.S. patent application Ser. No. 12/532,030, filed on Mar. 23, 2009, entitled “semiconductor memory and manufacturing method thereof”. The entire contents of the above-identified patent applications are incorporated by reference in the present application.

A plurality of cell transistors connected to the same word line WL in a plurality of strings of a single string group STRG form a physical unit. A memory space of a single physical unit forms one or a plurality of pages. One page may be formed by a memory space of some cell transistors of a physical unit. Data is read in the page unit. Writing may be performed for each page or for each physical unit.

In each physical block MB, the word lines with the same number in different strings are connected to each other. In other words, for example, the word lines WL0 of all the strings in a single physical block are connected to each other, and the word lines WLX are connected to each other.

For access to the cell transistor MTr, one of the physical blocks is selected, and one of the string groups STRG is selected. In order to select a physical block, a signal for selecting the physical block is output only to a physical block which is specified using a physical block address signal. In the selected physical block, the word line WL, and the selection gate lines SGSL and SGDL are connected to the driver by using the signal for selecting the physical block. From the above description, a physical block may be defined as different strings sharing a word line and sharing a single row decoder.

In addition, in order to select one of the string group STRG, a selection voltage is applied to the selection transistors SSTr and SDTr only in a selected string group STRG. In an unselected string group STRG, a non-selection voltage is applied to the selection transistors SSTr and SDTr. The selection voltage depends on operations such as reading and writing. Similarly, the non-selection voltage also depends on operations such as reading and writing.

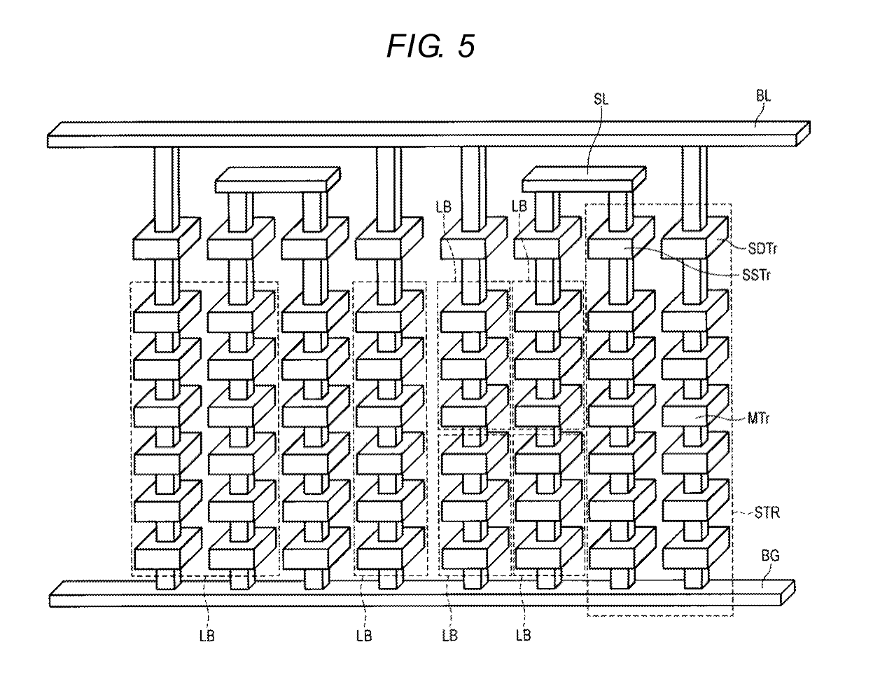

The memory 10 is configured such that data may be erased in the physical block unit. In addition, the memory 10 is configured such that data may also be erased in the logical block LB unit in a physical block. The logical block LB, as shown in FIG. 5, includes, for example, a single string group, or a plurality of string groups such as two string groups. Here, FIG. 5 shows only elements for a single bit line BL, and thus a string STR is shown instead of a string group. Alternatively, the logical block LB includes some memory strings MS of a plurality of respective strings of a single string group. Specifically, the logical block LB includes a half of one memory string MS, and a half string group which is arranged in the row direction along the half memory string in a string group to which the half memory string belongs. The half memory string is, for example, a half of one memory string MS located on one side of the back gate transistor BTr. Alternatively, the logical block LB includes a quarter of one memory string MS, and a quarter memory string group which is arranged in the row direction along the quarter memory string in a string group to which the quarter memory string belongs. The quarter memory string is, for example, a set of cell transistors MTr located on the upper side or the lower side in the stacking direction of the half memory string. Any defined logical block LB may be used, and the exemplary embodiment does not depend on a definition of the logical block LB.

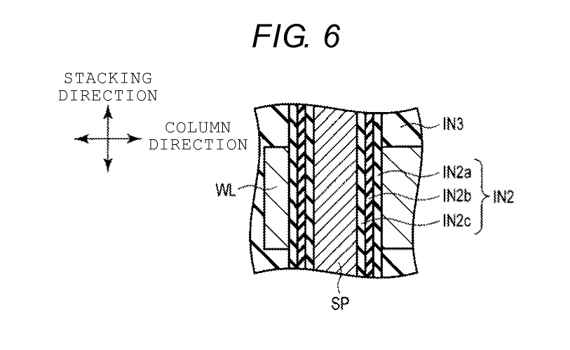

The cell transistor MTr has a structure shown in FIG. 6, for example. FIG. 6 is a cross-sectional view of the cell transistor according to the exemplary embodiment. The word line (gate) WL is made of, for example, polysilicon or polycide. A plurality of word lines WL, and a hole which penetrates through an insulating film therebetween, are formed. An insulating film IN2 is formed on the surface of the hole, and the semiconductor pillar SP is formed inside the hole. The semiconductor pillar SP extends in the stacking direction, is arranged in a matrix along a plane formed by the row direction and the column direction, and is made of a semiconductor (for example, silicon) doped with impurities.

The insulating film IN2 includes a tunnel insulating film IN2a, a charge storage film IN2b, and an interelectrode insulating film IN2c. The tunnel insulating film IN2a is made of, for example, silicon oxide (SiO₂). The charge storage film IN2b is formed on the tunnel insulating film IN2a. The charge storage film IN2b stores electric charge, and is made of, for example, silicon nitride (SiN). The interelectrode insulating film IN2c is formed on the charge storage film IN2b. The interelectrode insulating film IN2c is made of, for example, silicon oxide. A cell current which flows through the semiconductor pillar SP varies depending on a potential of the word line WL and the number of carriers in the charge storage film IN2b, and the cell transistor MTr stores data in a nonvolatile manner by using the variation in the cell current.

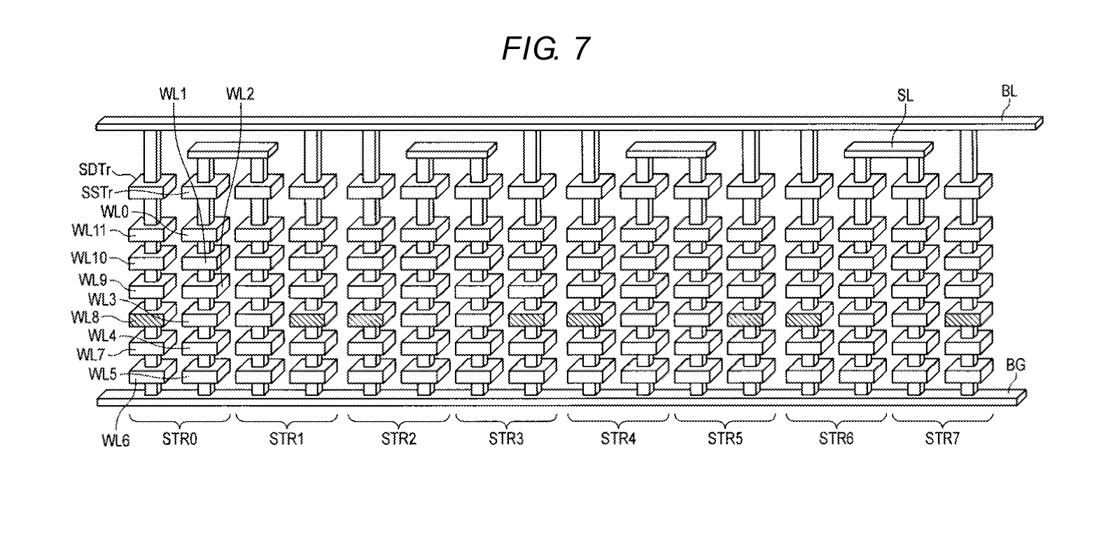

FIG. 7 shows an example of voltages in various elements when reading and writing are performed in the memory 10, that is, voltage biases when reading and writing are performed. FIG. 7 shows an example in which a single memory string includes twelve memory cells. In addition, FIG. 7 shows only some elements related to a single bit line BL, and also in the following description, the elements shown in FIG. 7 will be described. However, the same description is also applied to a string group STRG (that is, a front or rear string in FIG. 7) to which a mentioned string belongs. Although not shown in FIG. 7, the cell transistors MTr0 to MTr11 are respectively formed at locations intersecting the word lines WL0 to WL11 of the semiconductor pillar SP. FIG. 7 shows an example in which the string STR0 is selected, and the cell transistor MTr8 of the string STR0 is selected.

When reading is performed, a voltage Vsg for reading data from the selected string is applied to the gates of the selection gate transistors SDTr and SSTr of the selected string STR0. On the other hand, a voltage Vss is applied to the selection gate transistors of the unselected strings STR1 to STR7. In addition, a reading voltage Vcgrv is applied to the selected cell transistor MTr8 in the word line (selected word line) WL8. The voltage Vcgrv has a value corresponding to data held by the cell transistor MTr8. The cell to which the voltage Vcgrv is hatched. On the other hand, a voltage Vread is applied to the other cell transistors MTr0 to MTr7 and MTr9 to MTr11 of the selected string STR in the respective word lines (unselected word lines) WL. The voltage Vread has a value capable of turning on the cell transistor MTr regardless of data held by the cell transistor MTr, that is, regardless of a threshold voltage of the cell transistor MTr. Therefore, the voltage Vread is higher than the voltage Vcgrv. As above, the voltage Vread is applied to the unselected cell transistors MTr of the selected string STR, that is, disturbance (reading disturbance) is given thereto.

As described above, the word lines WL with the same number are connected to each other in a single physical block. For this reason, the reading voltages Vcgrv and Vread are respectively applied to a selected word line WL and an unselected word line WL of the unselected string STR. Therefore, in the unselected string STR, applied voltages are different, but the selected word line WL and the unselected word line WL undergo reading disturbance together. The selected word lines WL of the unselected strings STR are also hatched. Specifically, when data is read from a single physical block, the voltage Vread is applied to each cell transistor MTr the number of times which is the same as (the number of cell transistors of a single string−1)×(the number of strings connected to a single bit line BL). This number of times corresponds to the square of the number of strings, and is much greater than in the planar memory. Further, when data is read from a single physical block, the voltage Vcgrv is applied to each cell transistor MTr the number of times which is the same as the number of strings per bit line. The voltage is applied to a selected cell the first time, and the voltage is applied to unselected cells, that is, a string STR to which the cell transistor belongs is unselected, the remaining number of times. This reading disturbance does not occur in a planar memory of 1 string/(physical) block.

When data is written, voltages Vpgm and Vpass are respectively applied to gates of a selected cell transistor and an unselected cell transistor. The voltage Vpgm is a writing voltage. The voltage Vpass is a voltage for an unselected cell, which is applied to a gate of an unselected cell transistor in order to write data only to a selected cell transistor in a string. In addition, a voltage Vsgd for writing data to a selected string is applied to the gate of the selection gate transistor SDTr of a selected string STR. Further, a voltage Vss is applied to the gate of the selection gate transistor SSTr of the selected string STR and the gates of the selection gate transistors SSTr and SDTr of the unselected strings STR.

Due to the above application of the voltages, disturbance also occurs when data is written. First, in a selected string STR, an unselected cell transistor MTr undergoes disturbance due to the application of the voltage Vpass. In addition, the writing voltages Vpgm and Vpass are respectively applied to a selected word line WL and an unselected word line WL in an unselected string STR due to word line interconnection in a single physical block. Therefore, also in the unselected string STR, the applied voltages are different but the selected word line WL and the unselected word line WL undergo disturbance (writing disturbance) together.

In a single physical block, a plurality of strings STR are connected to a single bit line. For this reason, when data is written to a single physical block, the voltage Vpass is applied to each cell transistor MTr the number of times which is the same as (the number of cell transistors of a single string−1)×(the number of strings connected to a single bit line BL). This number of times is also much greater than in the planar memory. Since influence of writing disturbance on the memory cell is reset through erasure, a countermeasure may be devised such that writing errors do not occur due to the number of times of applying the voltage Vpass after the erasure is performed (disturbance is reset). However, as described above, the memory 10 can erase data in the unit of a logical block smaller than a physical block. For this reason, in a single physical block, there is a probability that a certain cell transistor may continuously accumulate influence of disturbance without undergoing erasure. In other words, a worst case of writing disturbance cannot be defined in the memory 10. Therefore, in relation to this fact, the memory 10 cannot be designed based on the worst case of writing disturbance which is the same as in the planar memory.

In addition, when data is written to a single physical block, the voltage Vpgm is applied to each cell transistor MTr the number of times which is the same as the number of strings per bit line. The voltage is applied to a selected cell the first time, and the voltage is applied to unselected cells, that is, a string STR to which the cell transistor belongs is unselected, the remaining number of times. This phenomenon does not occur in the planar memory.

As described above, since the memory 10 undergoes disturbance different from disturbance in the planar memory, and influence thereof is also different, the same controller as in the planar memory cannot be used for the memory 10.

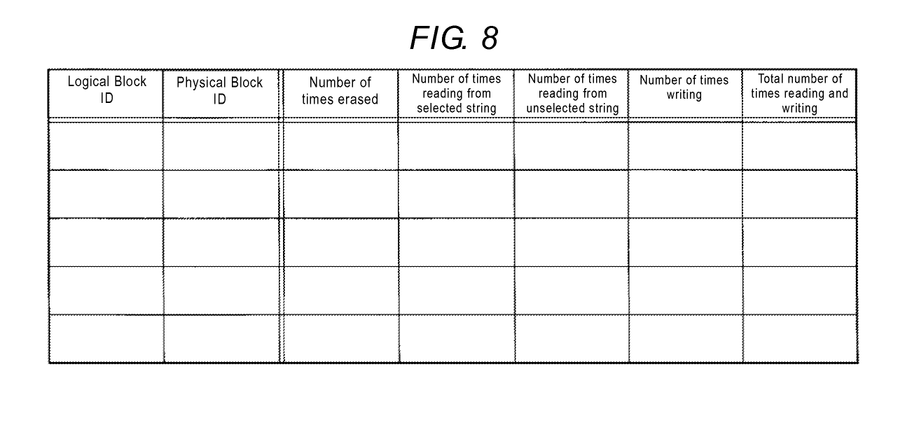

In order to manage this influence of disturbance on the memory 10, the memory controller 20 creates and holds a management table as shown in FIG. 8. FIG. 8 shows an example of a management table created by the memory controller according to the exemplary embodiment. For example, a program on the ROM 22 is executed by the CPU 21 such that the memory controller 20 creates a management table on the RAM 23.

As shown in FIG. 8, the management table is divided into a plurality of rows for each number (an ID or an address) of logical block LB. The management table indicates a variety of information for each logical block LB. In other words, the memory controller 20 manages a variety of information for each logical block LB. The information includes a number (an ID or an address) of a physical block, the number of times of erasure, the number of times of reading from a selected string, the number of times of reading from an unselected string, the number of times of writing, and the total number of times of reading and writing. The number of a physical block specifies a physical block to which a logical block LB belongs.

If data of a certain logical block LB is erased, the memory controller 20 increases the corresponding number of times of erasure by 1 and resets the number of times of reading or writing to zero.

If data is read from a memory cell connected to a certain selected word line WL, the memory controller 20 updates the number of times of reading from a selected string or an unselected string for a related logical block LB by predefined amounts depending on whether a certain logical block LB is included in a selected string STR or an unselected string STR, includes a selected word line, or the like.

If data is written to a cell transistor MTr connected to a certain selected word line WL, the memory controller 20 updates the number of times of writing for a related logical block LB by predefined amounts depending on whether a certain logical block LB is included in a selected string STR or an unselected string STR, or the like, as described later. FIG. 8 may include a new column.

In addition, if data is read from or written to a memory cell connected to a certain selected word line WL, the memory controller 20 increases the number of times of reading from or writing to a selected string for a related logical block LB by 1.

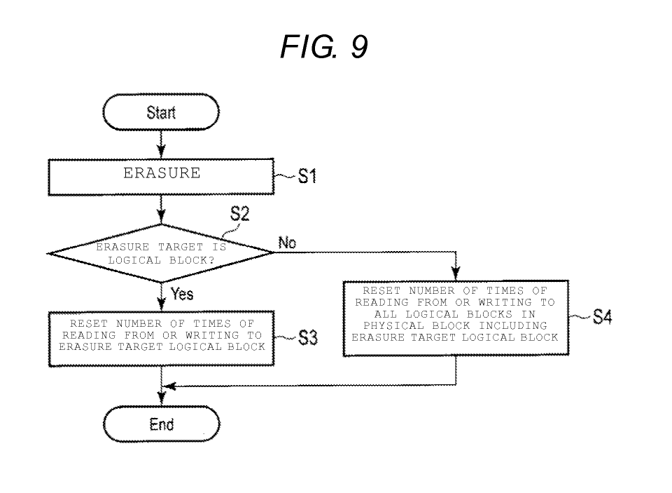

With reference to FIGS. 9 to 11, update of the management table of FIG. 8 will be described. FIGS. 9 to 11 are flowcharts illustrating update of the management table when the memory controller according to the exemplary embodiment performs erasure, reading and writing, respectively. The memory controller 20 is configured so as to perform processes of FIGS. 9 to 11. In other words, the CPU 21 performs the following processes on the basis of a program for controlling an operation of the memory controller 20, and the control program causes the CPU 21 to perform the following processes. The update of the management table may be performed before, after, or in the middle of respective corresponding operations such as erasure, reading and writing.

As shown in FIG. 9, the memory controller 20 starts a series of operations for erasure (step S1) and proceeds to step S2. In step S2, the memory controller 20 determines whether the erasure target is a logical block LB or a physical block (step S2). If a logical block LB is designated, the memory controller 20 updates the management table (FIG. 8) so as to increase the number of times of erasure by 1 and reset the number of times of reading or writing to zero in a row corresponding to the erasure target logical block LB (step S3). This is because influence of disturbance due to reading or writing hitherto is reset through the erasure, and thus the number of times of a set of reading and writing is counted again from 0. On the other hand, if the determination result in step S2 is negative, that is, a physical block is designated, the flow proceeds to step S4. In step S4, the memory controller 20 updates the management table so as to increase the number of times of erasure by 1 and reset the number of times of reading or writing to zero in rows corresponding to all logical blocks LB in the erasure target physical block. If the step S3 or S4 is completed, the flow finishes.

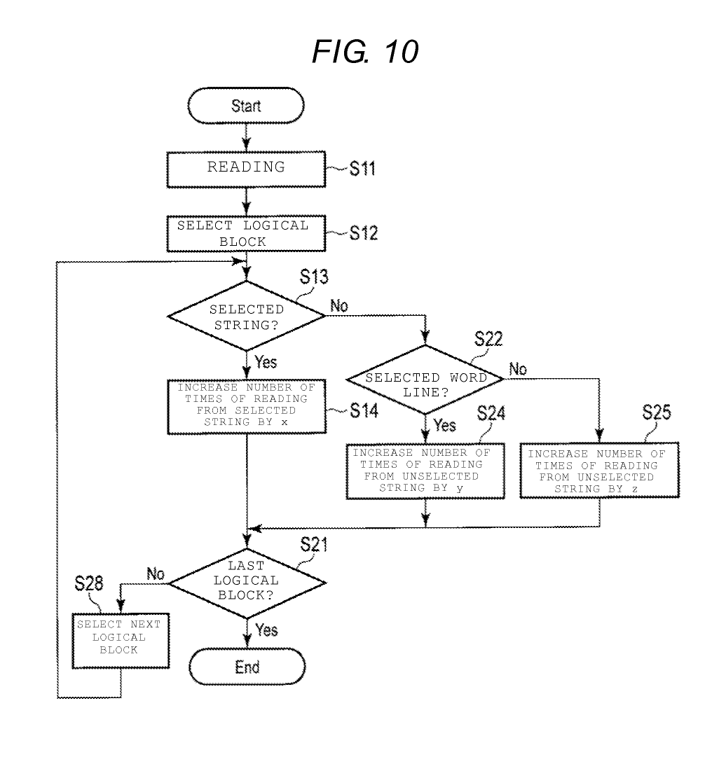

As shown in FIG. 10, the memory controller 20 starts a series of operations for reading data from a certain cell transistor MTr (step S11), and performs processes for updating the management table. In other words, the memory controller 20 updates the number of times of reading for all logical blocks LB in a physical block including the reading target cell transistor MTr. This is because the reading causes disturbance over a physical block to which a selected word line WL belongs. For example, the memory controller 20 updates all the logical blocks LB related to the reading in ascending order of numbers (addresses) thereof. FIG. 10 shows such an example. However, performing necessary update is not limited to the method shown in FIG. 10.

In step S12, the memory controller 20 determines a logical block LB which is an update target. Next, in step S13, the memory controller 20 determines whether or not the current logical block LB which is an update target is included in a selected string. If the current logical block LB is included in the selected string STR, the memory controller 20 updates the management table so as to adjust the number of times of reading from the selected string by x in a row corresponding to the current logical block LB. Here, x will be described later.

On the other hand, if the current logical block LB is included in an unselected string, the flow proceeds to step S22. In step S22, the memory controller 20 determines whether or not the current logical block LB includes a selected word line WL. If the determination result in step S22 is affirmative, the flow proceeds to step S24. In step S24, the memory controller 20 updates the management table so as to adjust the number of times of reading from the unselected string by y in a row corresponding to the current logical block LB. If the determination result in step S22 is negative, the flow proceeds to step S25. In step S25, the memory controller 20 updates the management table so as to adjust the number of times of reading from the unselected string by z in a row corresponding to the current logical block LB.

Steps S14, S24 and S25 are all followed by step S21. In step S21, the memory controller 20 determines whether or not the number of times for all logical blocks LB (in a single physical block) which should be updated is updated. If the determination result in step S21 is affirmative, the flow finishes. On the other hand, if the determination result in step S21 is negative, the memory controller 20 selects an unupdated logical block LB in order to update information for an unupdated logical block LB. As in this example, if the logical blocks LB are scanned in ascending order, the memory controller 20 increases the current logical block LB by 1 (step S28). Step S28 is followed by step S12.

The adjustment numbers x, y and z will be described. A string STR undergoes reading disturbance due to application of the voltage Vread regardless of whether or not the string is selected. For this reason, first, when data is read from a cell transistor MTr connected to a certain selected word line WL, the number of times of reading from a physical block including the selected cell transistor MTr is counted. However, influence of disturbance is different depending on whether a certain logical block LB is included in a selected string STR or an unselected string STR, or includes a selected word line WL. Therefore, the adjustment of the number of times of reading is weighted based on this condition.

The voltage Vread is high, and thus the voltage Vread rises a threshold voltage of a cell to which the voltage Vread is applied in a selected string STR. A frequency thereof is 1/(the number (i+1) of strings connected to a single bit line BL), and is limited. A frequency for an unselected string is (the number of strings connected to a single bit line BL−1)/(the number (i+1) of strings connected to a single bit line BL) and is thus high.

In addition, since the unselected string STR is disconnected and is thus electrically floated, a channel of the cell transistor MTr thereof is boosted by a voltage applied to the word line WL. Therefore, a channel voltage in the unselected string STR is substantially the same as the voltage Vread. Further, since the selected word line WL has the voltage Vcgrv (<Vread), electrons are extracted from the charge storage film IN2b, and thus a threshold voltage of the cell transistor MTr connected to the selected word line WL is reduced. Therefore, a value y for a logical block LB including the selected word line WL in the unselected string STR is a negative value. In addition, based on the fact that the channel is boosted in the unselected string STR, influence of reading disturbance on the unselected string STR is smaller than on the selected string STR. A magnitude of y is determined based on a relative relationship between this fact and a frequency in which x increases. For example, a value y for an unselected string is smaller than, is substantially the same as, or is the same as, for example, a value x for a selected string.

In addition, an unselected word line WL in an unselected string STR will also be examined. As described above, in the unselected string STR, a channel voltage is substantially Vread, and a voltage of the unselected word line WL is also Vread. However, when the unselected word line WL rises to the voltage Vread in a state in which the channel is charged to the voltage Vread, there is a potential difference between the channel and the unselected word line WL. This potential difference acts as disturbance. The disturbance occurs only for a short time, and thus a one-time magnitude thereof is small. For this reason, the disturbance may be disregarded. However, on the other hand, a frequency thereof is high. Therefore, a value z for a logical block LB including the unselected word line WL in the unselected string STR is defined. In addition, z is also a negative value in the same manner as the value y as is clear from the above description. The value z is determined in consideration of the one-time magnitude and frequency. At least |y|>|z| is given.

Based on the above examined items and characteristics of the memory 10, x, y, and z are determined. As an example, x is 1, y is −0.005, and z is −0.001.

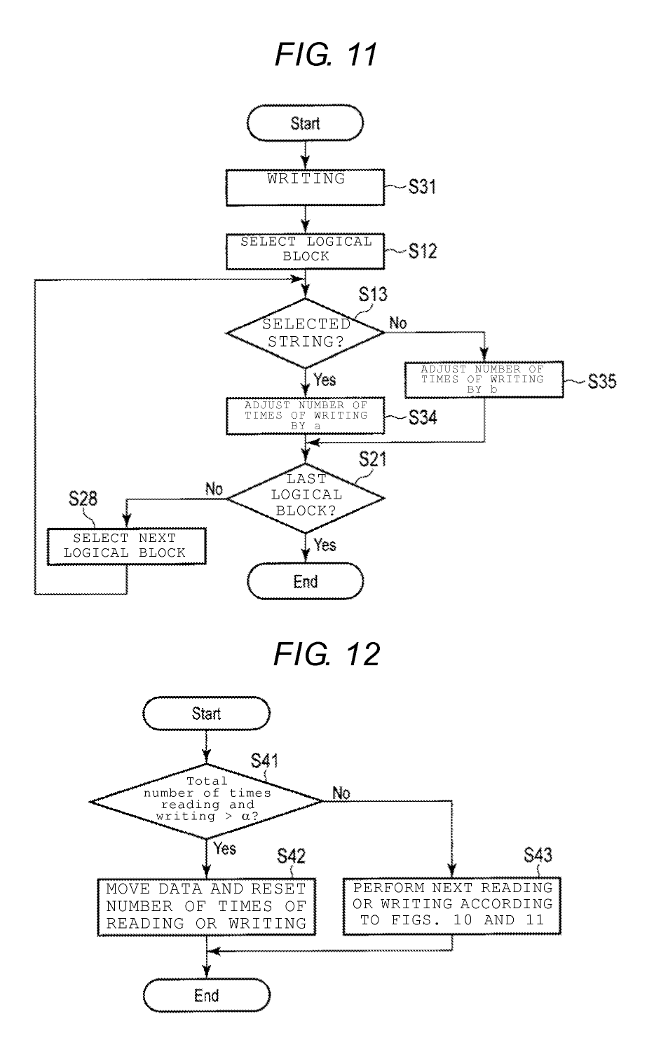

As shown in FIG. 11, the memory controller 20 starts a series of operations for writing data to a certain cell transistor MTr (step S31), and performs processes for updating the management table. In other words, the memory controller 20 updates the number of times of writing for all logical blocks LB in a physical block including a writing target cell transistor MTr. This is because the writing causes disturbance over a physical block to which a selected word line WL belongs. For example, the memory controller 20 updates all the logical blocks LB related to the writing in ascending order of numbers (addresses) thereof. FIG. 11 shows such an example. However, performing necessary update is not limited to the method shown in FIG. 11.

Step S31 is subsequent to the same step S12 as in FIG. 10, and the flow reaches step S13. If the current logical block LB is determined as being included in a selected string STR in step S13, the memory controller 20 updates the management table so as to adjust the number of times of writing in a row corresponding to the current logical block LB by a (step S34). On the other hand, if the current logical block LB is determined as being included in an unselected string STR, the memory controller 20 updates the management table so as to adjust the number of times of writing in a row corresponding to the current logical block LB by b (step S35). Here, a and b will be described later.

The same step S21 as in FIG. 10 follows all of steps S34 and 35. If it is determined that there is an unupdated logical block LB in step S21, the flow proceeds to step S28. Step S28 is followed by step S12.

The adjustment numbers a and b will be described. A string STR undergoes writing disturbance due to application of the voltage Vpass regardless of whether or not the string is selected. In a selected string STR, a channel voltage is Vss, and thus an unselected cell transistor MTr undergoes large disturbance due to the voltage Vpass and the channel voltage. However, in the same manner as in reading, a frequency thereof is 1/(the number (i+1) of strings connected to a single bit line BL), and is thus limited. On the other hand, since the unselected string STR is disconnected and is thus electrically floated, a channel of the cell transistor MTr thereof is boosted by a voltage applied to the word line WL. Therefore, a potential difference between the word line WL and the channel is smaller than in the selected string STR, and thus reading disturbance in the unselected string STR is weak. On the other hand, a frequency thereof is (the number of strings connected to a single bit line BL−1)/(the number (i+1) of strings connected to a single bit line BL) and is much higher than in the selected string STR. For this reason, a and b have different values on the basis of differences in the magnitude and the frequency of reading disturbance in the selected string STR and the unselected string STR. Values of a and b are determined based on differences in the magnitude and the frequency of disturbance in the selected and unselected strings STR based on characteristics of the memory 10. Here, b>>a is given. As an example, a is 0.001, and b is 1.

Through the above-described management of the table, a logical block LB which is not reset but accumulates influence of disturbance therein can be specified. Through this specification, the memory controller 20 can perform a necessary process, for example, copying any data to a separate region. As an example, movement of data using the number of times of reading or writing will be described with reference to FIG. 12. FIG. 12 is a flowchart illustrating movement of data using the management table. The memory controller 20 monitors the number of times of reading or writing of the management table in FIG. 8. For example, when the number of times of reading or writing for a certain logical block ID is updated, the memory controller 20 executes the flow of FIG. 12 in relation to the updated number of times of reading or writing. As shown in FIG. 12, the memory controller 20 determines whether or not the monitored number of times of reading or writing exceeds a value α (step S41).

If the determination result in step S41 is affirmative, the memory controller 20 moves data of a logical block ID of the monitored number of times of reading or writing to a region of which erasure is completed (step S42). In addition, in step S42, the memory controller 20 resets the monitored number of times of reading or writing. Therefore, the flow finishes. On the other hand, if the determination result in step S41 is negative, the memory controller 20 performs next reading or writing (step S43). This reading or writing corresponds to the reading or writing in FIG. 10 or 11, that is, includes update of the management table according to the exemplary embodiment. If step S43 is completed, the flow finishes.

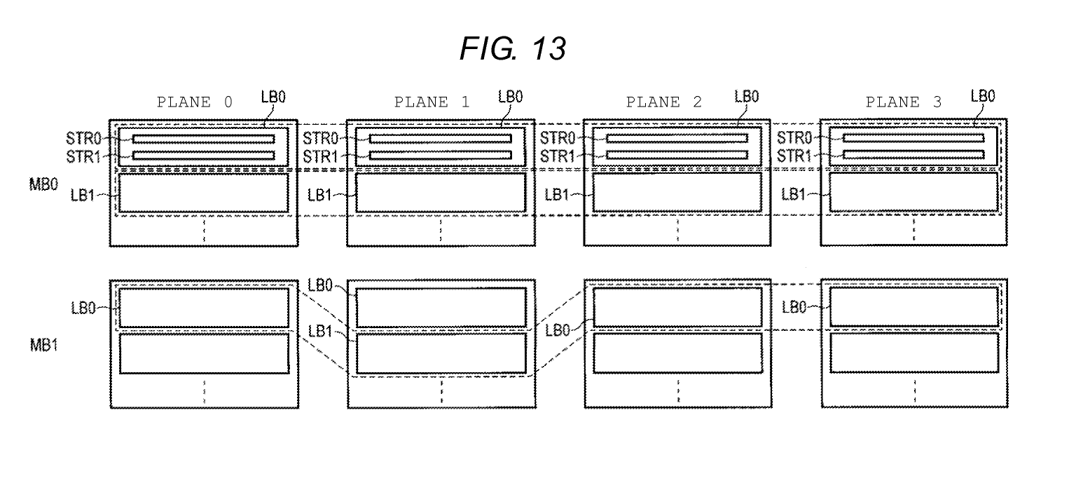

As described above, the memory 10 includes a plurality of planes. The management table may be common to a plurality of planes. In other words, as shown in FIG. 13, respective logical blocks of the planes 0 to 4 form a logical set. FIG. 13 shows an example in which a single logical block LB includes two strings STR. For example, logical blocks LB0 of respective physical blocks MB0 of the planes 0 to 4 form a logical set. The elements forming the logical set are surrounded by the broken line. Reading, writing, erasing, and the like are performed in parallel on the elements forming the logical set. In addition, when reading, writing, and erasing are performed on the string groups 0 and 1 (a set of strings STR0 and a set of strings STR1) of the respective physical blocks MB0 of the planes 0 to 4, the number of times of erasure, the number of times of reading from a selected string, the number of times of reading from an unselected string, the number of times of writing, the number of times of reading or writing, and the like, are updated.

In FIG. 13, the logical block LB0 of the physical block MB1 of the plane 1 is poor. For this reason, the logical blocks LB0 of the respective physical blocks MB1 of the planes 0, 2 and 3 and the logical block LB1 of the physical block MB1 of the plane 1 form a logical set. In addition, this set is accessed in parallel, and the number of times of erasure, the number of times of reading from a selected string, the number of times of reading from an unselected string, the number of times of writing, and the number of times of reading or writing are managed in common.

As described above, the memory controller 20 according to the exemplary embodiment is used in a memory in which a plurality of strings are connected to a single bit line in a single physical block, and counts the number of times of erasure, reading, writing, and the like for each logical block LB different from a physical block. In addition, when reading and writing are performed on a certain string, the memory controller 20 also adjusts the number of times of reading and the number of times of writing for an unselected string by the number of times which is weighted differently from the adjustment for a selected string. As above, the memory controller 20 is appropriate for characteristics of the memory in which a plurality of strings are connected to a single bit line in a single physical block. Therefore, the memory controller 20 which may appropriately manage influence of disturbance in this memory can be realized.

In the above description, particularly, as described with reference to FIG. 10, when reading is performed, the memory controller 20 also manages the number of times of reading for an unselected string so as to reduce, particularly, the number of times of reading from an unselected string. For this reason, if the memory controller 20 uses the fact that the number of times of reading from a certain region of the memory 10 exceeds a threshold value as a condition of executing data movement, timing when the data movement starts may vary depending on previous reading. For example, when data is read from a certain region 10,000 times, data movement is assumed to occur. Further, it is assumed that the word line WL0 of the string STR0 of a certain physical block is selected and data is read therefrom, and other strings STR are not selected and data is not read therefrom in the same physical block. Then, if the number of times of reading from the string STR0 continuously increases and reaches 10,000 times, data movement related to the word line WL0 of the string STR0 occurs in the physical unit.

On the other hand, it is assumed that reading performed by selecting the word line WL0 of the string STR0 in a certain physical block is repeatedly performed while reading is performed by selecting other some strings STR. Then, if the number of times of the reading performed by selecting the word line WL0 of the string STR0 exceeds 10,000 times (for example, 12000 times), data movement related to the word line WL0 of the string STR0 occurs in the physical unit. This is because the number of times of reading from an unselected string STR is reduced. This comes into collision with an example in which the number of times of reading from an unselected string STR is not reduced as in the exemplary embodiment. In other words, if any string reaches a prescribed number of times of reading (for example, 10,000 times), data is moved from the string which reaches the prescribed number of times. The data movement is accompanied by reading, that is, if necessary as a result of certain reading, the data movement follows the reading. Hereinafter, variations in some voltage levels will be described when reading and reading followed by data movement are respectively performed.

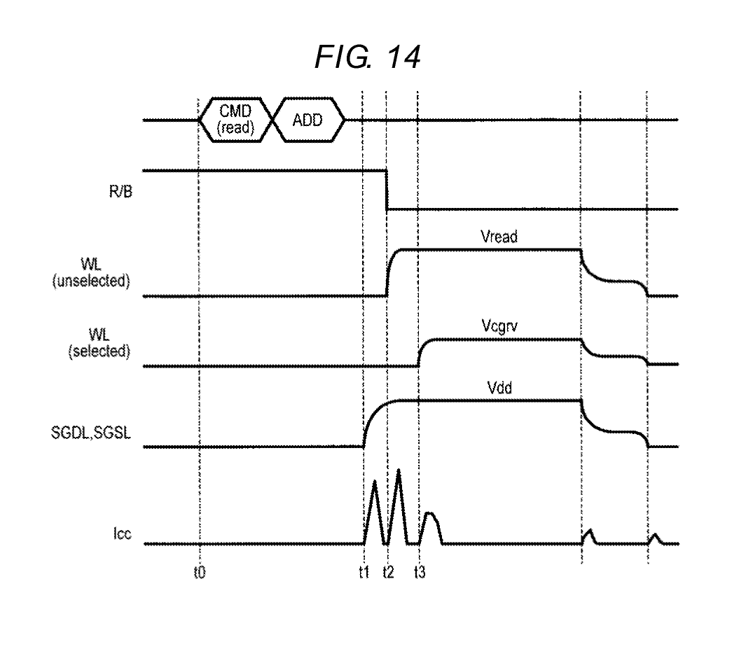

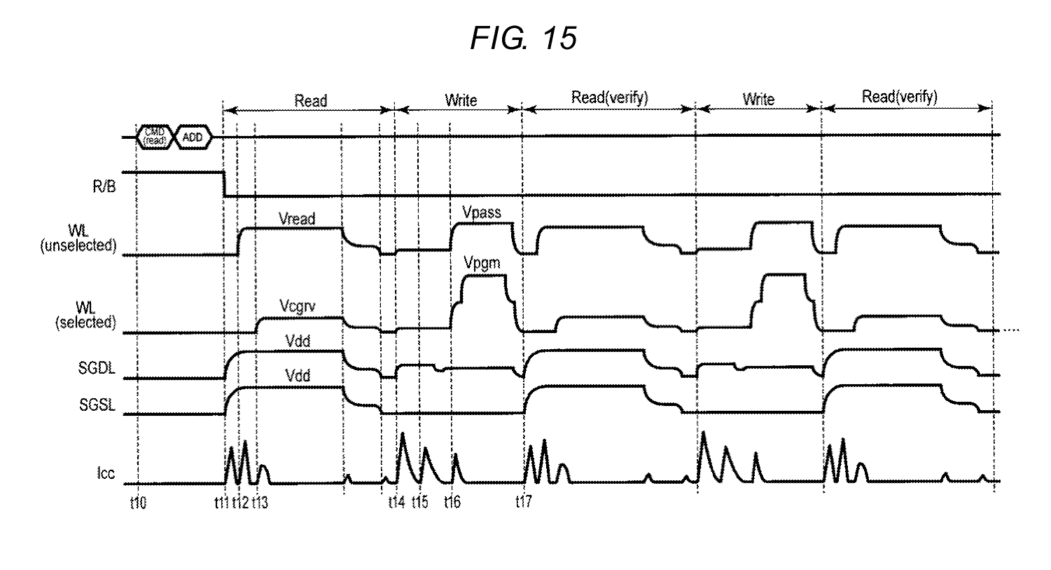

FIG. 14 is a time chart of some voltage levels when reading is performed according to the exemplary embodiment. FIG. 15 is a time chart of some voltage levels when reading followed by data movement is performed according to the exemplary embodiment. If the memory controller 20 receives a reading command and an address from an external device and data movement does not occur due to this reception, the memory controller 20 performs reading which is not accompanied by data movement. This case is shown in FIG. 14. As shown in FIG. 14, memory controller 20 receives a reading command and an address at the time point t0. In response thereto, at the time point t1, the memory 10 sets a ready/busy signal to a busy state, and the voltage Vdd is applied to the selection gate lines SGDL and SGSL so as to turn on the selection gate transistors SDTr and SSTr connected thereto. Subsequently, at the time point t2, the voltage Vread is applied to an unselected word line WL. Next, at the time point t3, the voltage Vcgrv is applied to a selected word line WL. According to the application of the voltages, a current Icc which is consumed in the memory 10 increases at the time points t1, t2 and t3.

On the other hand, if data movement occurs due to reception of the reading command and the address by the memory controller 20, the memory controller 20 performs reading accompanied by data movement. This case is shown in FIG. 15. First, in the same manner as in FIG. 14, the memory controller 20 receives the reading command and the address at the time point t10. In response thereto, at the time point t11, the memory 10 sets the ready/busy signal to a busy state, and, in the same manner as in FIG. 14, data is read. Successively, the memory controller 20 instructs the memory 10 to write the read data to a region different from a region from which the data is read. In response thereto, in the memory 10, a voltage for writing is applied to the selection gate line SGDL at the time point t14. Subsequently, the bit line BL is precharged at the time point t15. Next, at the time point t16, the voltages Vpass and Vpgm are respectively applied to an unselected word line WL and a selected word line WL. According to the application of the voltages, a consumed current Icc increases at the time points t14, t15 and t16. Successively, reading for verification is performed from the time point t17. An operation between the time points t17 and t18 is the same as between the time points t11 to t14. In addition, from the time point t18, writing and verification reading are repeatedly performed several times until writing succeeds.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A controller for a memory device comprising a bit line, a source line, and a plurality of strings connected between the bit line and the source line, each string including a plurality of memory cell transistors,
wherein the controller is configured to update first and second values for each string when a read operation is carried out on the strings, the first value for a first string being updated when the read operation is carried out on a memory cell transistor of the first string and the second value being updated when the read operation is carried out on a memory cell transistor of a second string that is different from the first string.

2. The controller according to claim 1, wherein the controller is configured to update a third value for each string when a write operation is carried out on the strings.

3. The controller according to claim 2, wherein the third value for the first string is increased by a first amount if the write operation is carried out on a memory cell transistor of the first string and by a second amount less than the first amount if the write operation is carried out on a memory cell transistor of the second string.

4. The controller according to claim 1, wherein the second value is decreased by a first amount if the first and second strings share word lines and by a second amount if the first and second strings do not share word lines.

5. The controller according to claim 1, wherein the controller is configured to update a third value for each string when a write operation is carried out on the strings, and to move data stored in memory cell transistors of a string to memory cell transistors of another string when a sum of the first, second, and third values of the string exceeds a first number.

6. The controller according to claim 5, wherein the controller is configured to perform an erase operation on the memory cell transistors of the string after the data stored in the memory cell transistors of the string have been copied to the memory cell transistors of said another string.

7. The controller according to claim 6, wherein the controller is configured to update the first, second, and third values for the string with zero values when an erase operation is performed on the string.

8. The controller according to claim 6, wherein the controller is configured to update a fourth value for a string when an erase operation is performed on the string, the fourth value indicating the number of times an erase operation has been performed on the string.

9. A controller for a memory device comprising a bit line, a source line, and a plurality of strings connected between the bit line and the source line, each string including a plurality of memory cell transistors,
wherein the controller is configured to update first and second values for each string when read operations are carried out on the strings, update third values for each string when write operations are carried out on the strings, and move data stored in memory cell transistors of a string to memory cell transistors of another string when a sum of the first, second, and third values of the string exceeds a first number.

10. The controller according to claim 9, wherein the controller is configured to perform an erase operation on the memory cell transistors of the string after the data stored in the memory cell transistors of the string have been copied to the memory cell transistors of said another string.

11. The controller according to claim 10, wherein the controller is configured to update the first, second, and third values for the string with zero values when an erase operation is performed on the string.

12. The controller according to claim 11, wherein the controller is configured to update a fourth value for a string when an erase operation is performed on the string, the fourth value indicating the number of times an erase operation has been performed on the string.

13. A memory device comprising:
a bit line;
a source line;
a plurality of strings connected between the bit line and the source line, each string including a plurality of memory cell transistors; and
a memory controller configured to update first and second values for each string when a read operation is carried out on the strings, the first value for a first string being updated when the read operation is carried out on a memory cell transistor of the first string and the second value being updated when the read operation is carried out on a memory cell transistor of a second string that is different from the first string.

14. The memory device according to claim 13, wherein the memory controller is configured to update a third value for each string when a write operation is carried out on the strings.

15. The memory device according to claim 14, wherein the third value for the first string is increased by a first amount if the write operation is carried out on a memory cell transistor of the first string and by a second amount less than the first amount if the write operation is carried out on a memory cell transistor of the second string.

16. The memory device according to claim 13, wherein the second value is decreased by a first amount if the first and second strings share word lines and by a second amount if the first and second strings do not share word lines.

17. The memory device according to claim 13, wherein the memory controller is configured to update a third value for each string when a write operation is carried out on the strings, and to move data stored in memory cell transistors of a string to memory cell transistors of another string when a sum of the first, second, and third values of the string exceeds a first number.

18. The memory device according to claim 17, wherein the memory controller is configured to perform an erase operation on the memory cell transistors of the string after the data stored in the memory cell transistors of the string have been copied to the memory cell transistors of said another string.

19. The memory device according to claim 18, wherein the memory controller is configured to update the first, second, and third values for the string with zero values when an erase operation is performed on the string.

20. The memory device according to claim 18, wherein the memory controller is configured to update a fourth value for a string when an erase operation is performed on the string, the fourth value indicating the number of times an erase operation has been performed on the string.
